(19) United States
(12) Patent Application Publication
(10) Pub. No.: US 2024/0154073 A1
(43) Pub. Date: May 9, 2024

(54) LIGHT-EMITTING DISPLAY DEVICE

(71) Applicant: Samsung Display Co., LTD., Yongin-si (KR)

(72) Inventors: Gak Seok LEE, Yongin-si (KR); Byung-Chul KIM, Yongin-si (KR); Jang Wi RYU, Yongin-si (KR); Jae Min SEONG, Yongin-si (KR); Keun Chan OH, Yongin-si (KR); Sang Hun LEE, Yongin-si (KR); HALIM JI, Yongin-si (KR)

(73) Assignee: Samsung Display Co., LTD., Yongin-si (KR)

(21) Appl. No.: 18/465,165

(22) Filed: Sep. 12, 2023

(30) Foreign Application Priority Data
Nov. 3, 2022 (KR) 10-2022-0145392

(51) Int. Cl. H01L 33/50; H01L 33/44

(52) U.S. Cl. CPC H01L 33/504; H01L 33/44

(57) ABSTRACT

According to embodiments, a light-emitting display device includes a light-emitting diode that emits blue light and green light, a color conversion layer on the light-emitting diode, and a scattering absorption layer disposed between the color conversion layer and the light-emitting diode and that transmits blue light and green light.

### CROSS-REFERENCE TO RELATED APPLICATION(S)

This application claims priority to and benefits of Korean Patent Application No. 10-2022-0145392 under 35 U.S.C. § 119 filed in the Korean Intellectual Property Office on Nov. 3, 2022, the entire contents of which are incorporated herein by reference.

### BACKGROUND

### 1. Technical Field

The described technology relates generally to a light-emitting display device.

### 2. Description of the Related Art

Display devices are devices that display images, and include a liquid crystal display (LCD), an organic light-emitting diode (OLED), and the like. Display devices have been used in various types of electronic devices, such as a cellular phone, a navigation system, a digital camera, e-book, a portable game console, and various types of terminals.

The OLED has self-luminance characteristics and does not need a light source unlike the LCD, thus contributing to reducing a thickness and weight thereof. The OLED has high-quality characteristics such as low power consumption, high luminance, and a high response rate.

The above information disclosed in this background section is only for enhancement of understanding of the background of the described technology, and therefore it may contain information that does not form the prior art that may already be known to a person of ordinary skill in the art.

### SUMMARY

The disclosure have been made in an effort to provide a light-emitting display device having advantages of reducing the reflection of external light.

Embodiments of the disclosure provide a light-emitting display device capable of reducing the reflection of external light and preventing a change in a reflected color to prevent degradation of display quality, and minimizing a reduction in light efficiency.

An embodiment provides a light-emitting display device including a light-emitting diode that emits blue light and green light, a color conversion layer on the light-emitting diode, and a scattering absorption layer disposed between the color conversion layer and the light-emitting diode that transmits blue light and green light.

The light-emitting diode may include an anode, a cathode, and three emission layers that emit blue light and an emission layer that emits green light, the emission layers disposed between the anode and the cathode.

The scattering absorption layer may have a transmittance of about 50% or more in a visible light wavelength band.

The light-emitting diode may include a first light-emitting diode, a second light-emitting diode, and a third light-emitting diode, the color conversion layer may include a red color conversion layer overlapping the first light-emitting diode, and a green color conversion layer overlapping the second light-emitting diode, and the light emitting display device may further include a transmission layer overlapping the third light-emitting diode.

The scattering absorption layer may overlap the red color conversion layer and include a cyan color filter.

The scattering absorption layer may overlap the green color conversion layer and include a cyan color filter.

The scattering absorption layer may overlap the red color conversion layer, the green color conversion layer, and the transmission layer.

The scattering absorption layer may include a cyan color filter.

The scattering absorption layer may be a film.

The light-emitting display device may further include a bank part disposed between the red color conversion layer, the green color conversion layer, and the transmission layer, and including a black pigment.

The light-emitting display device may further include an upper substrate, a red color filter disposed between the upper substrate and the red color conversion layer, a green color filter disposed between the upper substrate and the green color conversion layer, and a blue color filter disposed between the upper substrate and the transmission layer.

The light-emitting display device may further include a light blocking area including the red color filter, the green color filter, and the blue color filter overlap each other, in which the blue color filter among the red color filter, the green color filter, and the blue color filter in the light blocking area may be closest to the upper substrate.

The light blocking area may correspond to an overlapping part of the red color filter, the green color filter, and the blue color filter, and the light-emitting display device may further include a low refractive index layer disposed between the red color filter and the red color conversion layer, disposed between the green color filter and the green color conversion layer, and disposed between the blue color filter and the transmissive layer.

The light-emitting display device may further include a light blocking member disposed between the red color filter, the green color filter, and the blue color filter.

The light-emitting display device may further include a lower display panel including the light-emitting diode, and an upper display panel including the color conversion layer and the scattering absorption layer, in which the upper display panel may be formed of the same material as the scattering absorption layer and may further include a spacer configured to maintain a constant gap between the lower display panel and the upper display panel.

An embodiment provides a light-emitting display panel including a light-emitting diode that emits blue light, a color conversion layer disposed on the light-emitting diode, and a scattering absorption layer disposed between the color conversion layer and the light-emitting diode and including a blue color filter, in which the light-emitting diode may include an anode, a cathode, and three emission layers that emit blue light and disposed between the anode and the cathode.

The scattering absorption layer may have a transmittance of about 50% or more in a visible light wavelength band.

The light-emitting diode may include a first light-emitting diode, a second light-emitting diode, and a third light-emitting diode, the color conversion layer may include a red color conversion layer overlapping the first light-emitting diode, and a green color conversion layer overlapping the second light-emitting diode, the light emitting display device may further include a transmission layer overlapping the third light-emitting diode, and the scattering absorption layer may overlap the red color conversion layer.

The light-emitting display device may further include an upper substrate, a red color filter disposed between the upper substrate and the red color conversion layer, a green color filter disposed between the upper substrate and the green color conversion layer, and a blue color filter disposed between the upper substrate and the transmission layer.

The light-emitting display panel may further include a lower display panel including the light-emitting diode, and an upper display panel including the color conversion layer and the scattering absorption layer, in which the upper display panel and the scattering absorption layer may be formed of a same material and may further include a spacer that maintains a constant gap between the lower display panel and the upper display panel.

According to an embodiment, a scattering absorption layer overlapping at least some light conversion layers may be provided to absorb light reflected after being scattered by the light conversion layers, thereby reducing the reflection of external light.

According to an embodiment, color coordinate values of a reflected color may be prevented from being arbitrarily changed while reducing the reflection of external light by additionally forming a scattering absorption layer (RCC) without adjusting the transmittances of red light, green light, and blue light among the external light, thereby preventing deterioration of display quality and minimizing a reduction in light efficiency.

### BRIEF DESCRIPTION OF THE DRAWINGS

The above and other aspects and features of the disclosure will become more apparent by describing in detail embodiments thereof with reference to the attached drawings, in which:

FIG. 1 is an overall schematic cross-sectional view of a light-emitting display device according to an embodiment.

FIG. 2 is a schematic cross-sectional view of a light-emitting diode (LED) according to an embodiment.

FIGS. 3 and 4 are graphs showing characteristics of a scattering absorption layer according to an embodiment.

FIGS. 5 and 6 are schematic diagrams for describing characteristics of diffuse reflection.

FIG. 7 is a schematic diagram illustrating color coordinate characteristics of a light-emitting display device according to an embodiment.

FIG. 8 is a graph showing light efficiency of a light-emitting display device according to an embodiment.

FIG. 9 is a schematic cross-sectional view of an LED according to an embodiment.

FIG. 10 is a schematic cross-sectional view of a light-emitting display device according to an embodiment.

FIGS. 11 to 16 are schematic cross-sectional views of light-emitting display devices according to other embodiments.

FIG. 17 is a schematic diagram illustrating a schematic cross-sectional structure of a lower display panel according to an embodiment.

### DETAILED DESCRIPTION OF THE EMBODIMENTS

Hereinafter, various embodiments will be described in detail with reference to the accompanying drawings below so that they may be readily implemented by those of ordinary skill in the art. The disclosure may be embodied in many different forms and is not limited to the embodiments set forth herein.

For clarity, parts not related to explaining the disclosure may be omitted here, and the same reference numerals are allocated to the same or like components throughout the specification.

The size and thickness of each component are arbitrarily shown in the drawings for convenience of description and thus the disclosure is not necessarily limited thereto. In the drawings, the thicknesses of layers and regions are expanded for clarity. In the drawings, the thickness of some layers and regions are exaggerated for convenience of description.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that when an element such as a layer, a film, a region, a plate, or a component is referred to as being “on” or “above” another element, the element is “directly on” the other element or another element is interposed therebetween. In contrast, it will be understood that when an element is referred to as being “directly on” another element, there is no intervening element therebetween. When an element is referred to as being “on” or “above” a reference element, the element may be understood as being positioned on or below the reference element but should not necessarily be understood as being positioned on or above the reference element in a direction opposite to a direction of gravity.

It will be understood that throughout the specification, when an element is referred to as “including” another element, the element may further include other elements unless mentioned otherwise.

Throughout the specification, the expression “on a plane” should be understood to mean a portion of an object when viewed from above, and the term “on a cross section” should be understood to mean a portion of a vertically cut object when viewed from a side.

Throughout the specification, it will be understood that when two or more elements are referred to as being “connected” to each other, the two or more elements are connected directly to each other, connected indirectly to each other through another element, are physically connected to each other, are electrically connected to each other, or are connected to each other although they are referred to as different names according to positions or functions thereof but are substantially integrally formed are connected to each other.

Throughout the specification, when an element such as a wiring, a layer, a film, a region, a plate, or a component is referred to as “extending in a first or second direction”, the element should be understood as including not only a straight shape extending in the first or second direction but also a structure, for example, a bent, zigzag, or curved structure, that generally extends in the first or second direction.

Electronic devices that include a display device, a display panel or the like described herein (for example, a mobile phone, a TV, a monitor, a laptop computer, and the like) or electronic devices that include a display device, a display panel or the like manufactured by a manufacturing method described herein are not excluded from the scope of the disclosure.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The term “overlap” or “overlapped” means that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

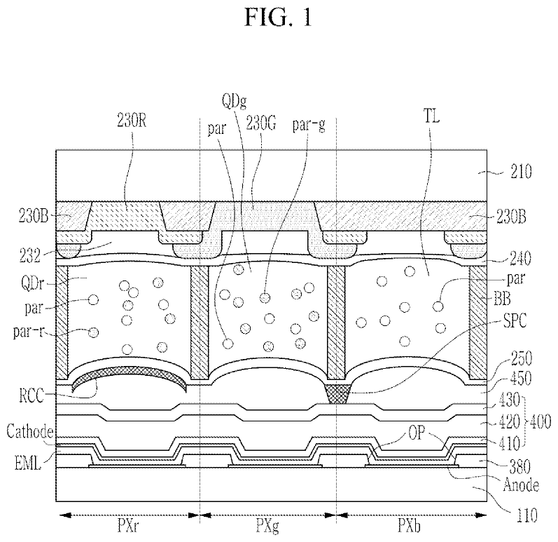

A schematic cross-sectional structure of an entire light-emitting display device will be described with reference to FIG. 1 below.

FIG. 1 is an overall schematic cross-sectional view of a light-emitting display device according to an embodiment.

FIG. 1 is a schematic cross-sectional view of three-color pixels PXr, PXg, and PXb among components of the light-emitting display device, in which a structure of a pixel circuit unit that transmits current to a light-emitting diode (LED) is omitted and an anode Anode and the like of the LED are schematically shown.

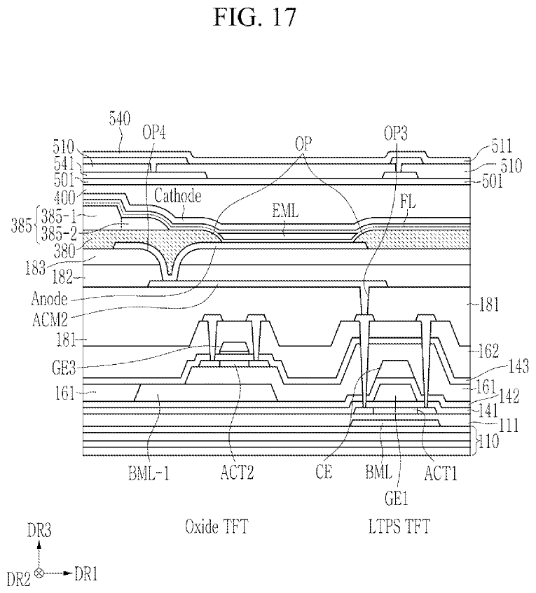

As shown in FIG. 1, an anode Anode is formed on a first substrate 110 (also referred to as a lower substrate) for each of the pixels PXr, PXg, and PXb. A structure of a pixel circuit unit, such as transistors, an insulating layer, etc., which is located between the first substrate 110 and the anode Anode, is omitted and is, for example, as shown in FIG. 17.

A pixel defining film 380 is provided on the anode Anode and may include an opening OP exposing a part of the anode Anode.

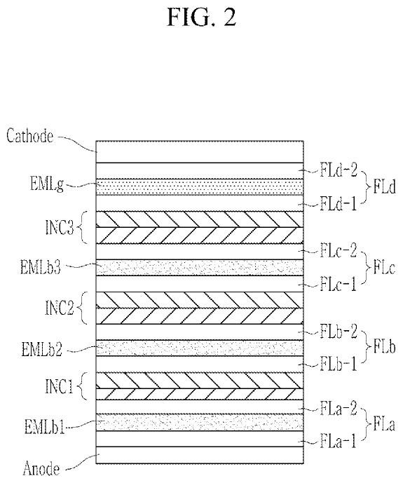

An emission layer EML may be provided on the anode Anode and the pixel defining film 380, and is positioned on entire areas of the anode Anode and the pixel defining film 380 in the embodiment. The emission layer EML may be an emission layer that emits light including blue light, and may have a structure including an emission layer and an intermediate layer adjacent thereto shown in FIG. 2. An intermediate layer (see FL of FIG. 17) may be further provided on the anode Anode and the pixel defining film 380 and below and on the emission layer EML. In an embodiment, emission layers EML may be formed to be separated from each other with respect to the opening OP of each pixel, and, emission layers of each pixel may emit light of different colors. A cathode Cathode may be provided on the entire emission layer EML. Here, the anode Anode, the emission layer EML, and the cathode Cathode form an LED, and an intermediate layer may also be included in the LED.

LEDs included in the pixels PXr, PXg, and PXb may be a first LED, a second LED, and a third LED, and the first to third LEDs may include the same emission layers EML that emit light of the same wavelength.

An encapsulation layer 400 including insulating layers 410, 420, and 430 may be provided on the cathode Cathode. The insulating layer 410 and the insulating layer 430 may include an inorganic insulating material, and the insulating layer 420 disposed between the insulating layer 410 and the insulating layer 430 may include an organic insulating material. According to an embodiment, the encapsulation layer 400 may include an insulating layer including an inorganic insulating material and an insulating layer including an organic insulating material.

The first substrate 110 to the encapsulation layer 400 are referred to together as a first display panel or a lower display panel.

A filling layer 450 including a filler may be provided on the encapsulation layer 400. Components on the filling layer 450 may be referred to together as a second display panel or an upper display panel, and a light-emitting display device may be formed by forming the lower display panel and the upper display panel and attaching them to each other by the filling layer 450.

An upper display panel including color conversion layers QDr and QDg and color filters 230R, 230G, and 230B is provided on the filling layer 450.

The upper display panel will be described on the basis of an order of manufacturing the upper display panel from a second substrate 210 (hereinafter, also referred to as an upper substrate).

The second substrate 210 may be formed of glass like the first substrate 110.

The color filters 230R, 230G, and 230B are positioned below the second substrate 210.

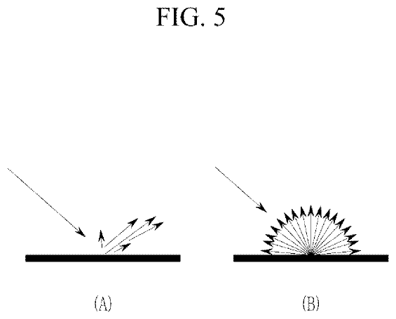

The red color filter 230R may transmit red light, the green color filter 230G may transmit green light, and the blue color filter 230B may transmit blue light. An area in which at least two of the red color filter 230R, the green color filter 230G, and the blue color filter 230B overlap each other may be an area that does not transmit light (hereinafter referred to as a light blocking area), and an area in which one color filter 230R, 230G or 230B is located and which transmits light and displays an image may be a transmissive area. The light blocking area may be configured to divide the transmissive area and be located between adjacent transmissive areas. In the embodiment of FIG. 1, the light blocking area that does not transmit light is formed by arranging the three color filters 230R, 230G, and 230B to overlap one another without forming a light blocking member. In the embodiment of FIG. 1, the blue color filter 230B is positioned on an uppermost part of the light blocking area close to the second substrate 210. The position of the blue color filter 230B is determined on the basis of a relatively low external light reflectance thereof. For example, the blue color filter 230B is formed in a large area below or directly below the second substrate 210 so that the reflectance of external light may be low in case that the external light is incident. The reflection of external light may be divided into specular reflection (see FIG. 5A) and diffuse reflection (see FIG. 5B), and the specular reflection may decrease due to a reduction of a reflectance by the blue color filter 230B. In an embodiment, a light blocking member may be additionally provided on the light blocking area in which the color filters 230R, 230G, and 230B overlap one another, and, the blue color filter 230B may be positioned closest to the second substrate 210 rather than the light blocking member.

The height of the light blocking area is high because the color filters 230R, 230G, and 230B overlap one another in the light blocking area, and the height of the transmissive area is low because only one color filter is located in the transmissive area. A low refractive index layer 232 is provided below the transmissive area of the color filters 230R, 230G, and 230B. The low refractive index layer 232 is a layer with a lower refractive index than that of a layer adjacent thereto, and may include an organic material. In case that light emitted from the emission layer EML travels to the outside due to the low refractive index layer 232, the light travels while the angle thereof with respect to a normal of the low refractive index layer 232 decreases, thus improving front luminance. The low refractive index layer 232 may cause a step difference between the transmissive area and the light blocking area of the color filters 230R, 230G, and 230B to be removed or reduced. In an embodiment, the low refractive index layer 232 may also be provided below the light blocking area formed due to the overlapping of the color filters 230R, 230G, and 230B.

A first passivation layer 240 is provided below the color filters 230R, 230G, and 230B and the low refractive index layer 232. The first passivation layer 240 may be an insulating layer that allows additional layers (a bank part BB, the color conversion layers QDr and QDg, and a transmission layer TL) to be readily formed below the color filters 230R, 230G, 230B and the low refractive index layer 232.

Bank parts BB are positioned below portions of the first passivation layer 240 corresponding to the light blocking area, one of the color conversion layers QDr and QDg and the transmission layer TL is positioned between bank parts BB, and the color conversion layers QDr and QDg and the transmission layer TL correspond to the transmissive area.

The bank parts BB may be formed of an organic material including black pigment that does not transmit light. The bank part BB may be configured to divide the transmissive area on which the color conversion layers QDr and QDg or the transmission layer TL is located, similar to the light blocking area, and may be located between adjacent transmissive areas. Although FIG. 1 illustrates that the bank part BB has a uniform width, the bank part BB may be a tapering part having a wider upper or lower part.

The color conversion layers QDr and QDg and the transmission layer TL located in the transmissive area will be described below.

First, the transmission layer TL may pass light incident thereon. For example, the transmission layer TL may directly transmit light emitted from the emission layer EML. Light emitted from the emission layer EML may include blue light, and blue light is provided to the outside as light sequentially passes through the transmission layer TL and the blue color filter 230B above the transmission layer TL. The transmission layer TL may include a polymer material that transmits light emitted from the emission layer EML. An area in which the transmission layer TL is located may correspond to an emission area that emits blue light, and the transmission layer TL does not include a semiconductor nanocrystal but may include a scattering member part that refracts and disperses light. In an embodiment, the scattering member part may be formed of TiO₂ and may allow light to be scattered in various directions.

The color conversion layers QDr and QDg may include different semiconductor nanocrystals par-r and par-g. For example, light that is emitted from the emission layer EML and incident on the red color conversion layer QDr may be emitted after being converted into red light by the semiconductor nanocrystal par-r included in the red color conversion layer QDr. Light that is emitted from the emission layer EML and incident on the green color conversion layer QDg may be emitted after being converted into green light by the semiconductor nanocrystal par-g included in the green color conversion layer QDg.

The semiconductor nanocrystals par-r and par-g may include at least one of a phosphor or a quantum dot material that converts incident light emitted from the emission layer EML into red or green light.

As used herein, quantum dots refer to crystals of a semiconductor compound, and may include a material that emits light of various emission wavelengths according to the size of the crystals or as a result of adjusting a ratio of elements of a quantum dot compound.

A diameter of the quantum dots may be, for example, in a range of about 1 nm to about 10 nm.

The quantum dots may be synthesized by a wet chemical process, an organic metal chemical vapor deposition process, a molecular beam epitaxy process, or the like within the spirit and the scope of the disclosure.

The wet chemical process is a method of growing quantum dot particle crystals after mixing an organic solvent and a precursor material. In the wet chemical process, the organic solvent serves as a dispersant that is naturally coordinated on surfaces of the quantum dot crystals and controls the growth of the crystals in case that the crystals are grown, and thus, the growth of the quantum dot particles can be controlled at lower costs and more readily than in a vapor deposition method such as MOCVD or MBE.

The quantum dots may include a Group III-VI semiconductor compound, a Group II-VI semiconductor compound, a Group III-V semiconductor compound, a Group III-VI semiconductor compound; a Group I-III-VI semiconductor compound; a Group IV-VI semiconductor compound; a Group IV element or compound; or a combination thereof.

Examples of the Group II-VI semiconductor compound may include: a binary compound such as CdS, CdSe, CdTe, ZnS, ZnSe, ZnTe, ZnO, HgS, HgSe, HgTe, MgSe, or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quarternary compound such as CdZnSeS, CdZnSeTe, CdZnSTe, CdHgSeS, CdHgSeTe, CdHgSTe, HgZnSeS, HgZnSeTe, or HgZnSTe; and a combination thereof.

Examples of the Group III-V semiconductor compound may include: a binary compound such as GaN, GaP, GaAs, GaSb, AlN, AlP, AlAs, AlSb, InN, InP, InAs, or InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, or GaAlNP; a quarternary compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; and a combination thereof. The Group III-V semiconductor compound may further include a Group II element. Examples of the Group III-V semiconductor compound, including the Group II element, may include InZnP, InGaZnP, InAlZnP, and the like within the spirit and the scope of the disclosure.

Examples of the Group III-VI semiconductor compound include a binary compound such as GaS, Ga₂S₃, GaSe, Ga₂Se₃, GaTe, InS, InSe, In₂Se₃, or InTe, a ternary compound such as InGaS₃, or InGaSe₃, and a combination thereof.

Examples of the Group I-III-VI semiconductor compound may include: a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO₂, a quarternary compound such as AgInGaS₂ or AgInGaSe₂; and a combination thereof.

Examples of the Group IV-VI semiconductor compound may include a binary compound such as SnS, SnSe, SnTe, PbS, PbSe, or PbTe; a ternary compound such as SnSeS, SnSeTe, SnSTe, PbSeS, PbSeTe, PbSTe, SnPbS, SnPbSe, or SnPbTe; a quarternary compound such as SnPbSSe, SnPbSeTe, or SnPbSTe; and a compound thereof.

The Group IV element or compound may include a single compound such as Si or Ge, a binary compound such as SiC or SiGe, or a combination thereof.

Each element included in a multi-element compound such as a binary compound, a ternary compound, or a quarternary compound may be in particles at a uniform concentration or a non-uniform concentration. For example, a chemical formula represents the types of elements included in a compound, and a ratio of the elements of the compound may vary. For example, AgInGaS₂ may be AgInₓGa₁₋ₓS₂ (x is a real number between 0 and 1).

The quantum dots may have a single structure or a core-shell double structure in which the concentration of each element included in the quantum dots is uniform. For example, a material contained in a core and a material contained in a shell may be different from each other.

The shell of the quantum dots may serve as a protective layer for preventing chemical deformation of the core to maintain semiconductor properties and/or as a charging layer for providing electrophoresis properties to the quantum dots. The shell may be a single layer or multiple layers. An interface between the core and the shell may have a concentration gradient, so that the concentration of elements in the shell decreases toward the center of the interface.

Examples of the shell of the quantum dots may include a metal or non-metal oxide, a semiconductor compound, and a combination thereof. Examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; and a combination thereof. Examples of the semiconductor compound may include a Group III-VI semiconductor compound, a Group II-VI semiconductor compound, a Group III-V semiconductor compound, a Group III-VI semiconductor compound, a Group I-III-VI semiconductor compound, a Group IV-VI semiconductor compound, and a combination thereof as described above. Examples of the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, and a combination thereof.

Each element included in a multi-element compound such as a binary compound or a ternary compound may be present in particles at a uniform concentration or a non-uniform concentration. For example, a chemical formula represents the types of elements included in a compound, and a ratio of the elements of the compound may vary.

The quantum dots may have a full width of half maximum (FWHM) of an emission wavelength spectrum of less than about 45 nm, for example, less than about 40 nm, and for example, less than about 30 nm, and color purity or color reproducibility may be improved in the above range. Light is emitted from the quantum dots in all directions, thus improving optical viewing angle.

For example, the quantum dots may have a spherical shape, a pyramid shape, a multi-arm shape, cubic nanoparticle shape, a nano tube shape, a nanowire shape, a nanofiber shape, or a nano-plate particle shape.

Light in various wavelength bands may be obtained from a quantum dot emission layer by adjusting an energy band gap by adjusting the size of the quantum dots or a ratio of elements of a quantum dot compound. Therefore, it is possible to implement a light-emitting device that emits light of various wavelengths by using quantum dots as described above (quantum dots of different sizes or quantum dots in which a ratio of elements of a quantum dot compound is changed). For example, the size of the quantum dots or the adjustment of the ratio of elements of the quantum dot compound may be selected to emit red, green, and/or blue light. The quantum dots may be configured to emit white light by combining light of various colors.

The color conversion layers QDr and QDg may further include a scattering member part in addition to the semiconductor nanocrystals par-r and par-g, similar to the transmission layer TL. Light emitted from the color conversion layers QDr and QDg may be refracted and dispersed by the scattering member part. In an embodiment, the scattering member part may be formed of TiO₂.

A second passivation layer 250 is provided below the bank parts BB, the color conversion layers QDr and QDg, and the transmission layer TL. The second passivation layer 250 is an insulating layer that protects the bank parts BB, the color conversion layers QDr, QDg, and the transmission layer TL in a subsequent process and helps layers (a scattering absorption layer RCC and a spacer SPC) to be readily formed in the subsequent process.

The scattering absorption layer RCC and the spacer SPC are provided below the second passivation layer 250. The scattering absorption layer RCC and the spacer SPC may be formed of the same material or a similar material by the same process. In the embodiment of FIG. 1, the scattering absorption layer RCC and the spacer SPC may be formed as cyan color filters that transmit blue light and green light. However, in an embodiment, the scattering absorption layer RCC and the spacer SPC may be formed of different materials, and the spacer SPC may not be a cyan color filter. However, in case that the same material or a similar material and the same process are used, the process may be simplified, thus reducing a manufacturing time.

In the embodiment of FIG. 1, the scattering absorption layer RCC including the cyan color filter is located only in an area overlapping the red pixel PXr and thus is formed only at a position overlapping the red color filter 230R and the red color conversion layer QDr. The scattering absorption layer RCC may be positioned between the red color conversion layer QDr and the anode Anode of the LED, and may transmit blue light and green light and absorb or block red light.

The spacer SPC may be formed at a position that corresponds to the light blocking area and that is higher than the scattering absorption layer RCC. Therefore, the spacer SPC may overlap the bank parts BB and the color filters 230R, 230G, and 230B overlapping one another but may not overlap the color conversion layers QDr and QDg or the transmission layer TL, and may not overlap the color filters 230R, 230G, and 230B that do not overlap one another. The second substrate 210 to the second passivation layer 250, the scattering absorption layer RCC, and the spacer SPC may form an upper display panel. The spacer SPC may maintain a constant interval between the upper display panel and the lower display panel.

The filling layer 450 may be positioned between the upper display panel and the lower display panel, surround the vicinity of the spacer SPC, be positioned below the second passivation layer 250 and the scattering absorption layer RCC, and be positioned on the encapsulation layer 400.

The schematic cross-sectional structure of the entire light-emitting display device has been described above with reference to FIG. 1. A stacked structure of an LED with an emission layer EML and a functional layer FL, which is available in the embodiment of FIG. 1, will be described with reference to FIG. 2 below.

FIG. 2 is a schematic cross-sectional view of an LED according to an embodiment.

Although FIG. 1 schematically illustrates only the emission layer EML between the cathode Cathode and the anode Anode of the LED, in the embodiment of FIG. 1, actually, a stacked structure including emission layers EML, a functional layer FL, etc. may be provided between a cathode Cathode and an anode Anode of an LED as shown in FIG. 2.

FIG. 2 illustrates a stacked structure of an LED having a tandem structure including emission layers EML. In the embodiment of FIG. 2, a total of four emission layers EML are included between an anode Anode and a cathode Cathode. Each of functional layers FLa, FLb, FLc, and FLd is provided on or below one of emission layer EMLb1, EMLb2, EMLb3, and EMLg, and intermediate connecting layers INC1, INC2, and INC3 are positioned between adjacent functional layers. For example, in the LED having the tandem structure of FIG. 2, the anode Anode, a first functional layer FLa-1 for a first emission layer, the first emission layer EMLb1, a second functional layer FLa-2 for the first emission layer, the first intermediate connecting layer INC1, a first functional layer FLb-1 for a second emission layer, the second emission layer EMLb2, a second functional layer FLb-2 for the second emission layer, the second intermediate connecting layer INC2, a first functional layer FLc-1 for a third emission layer, the third emission layer EMLb3, a second functional layer FLc-2 for the third emission layer, the third intermediate connecting layer INC3, a first functional layer FLd-1 for a fourth emission layer, the fourth emission layer EMLg, a second functional layer FLd-2 for the fourth emission layer, and the cathode Cathode may be sequentially stacked each other.

Here, at least one of the emission layers EMLb1, EMLb2, EMLb3, and EMLg may emit light of a different wavelength. In the embodiment of FIG. 2, the emission layers EMLb1, EMLb2, and EMLb3 emit light of a blue wavelength, and the emission layer EMLg emits light of a green wavelength. Therefore, the LED of FIG. 2 may emit blue light and green light. Here, the emission layers EMLb1, EMLb2, and EMLb3 that emit light of a blue wavelength may be formed of the same material or a similar material to emit light of the same wavelength or be formed of different materials to emit light in different wavelength bands among pieces of blue light. In case that the emission layer EMLg that emits green light is further provided as in the embodiment of FIG. 2, the light-emitting display device may further include a green light component to allow a user to sense more green and readily recognize green light, thereby improving display quality. However, even in case that the LED including the four emission layers EMLb1, EMLb2, EMLb3, and EMLg further emits green light, color filters 230R, 230G, and 230B are provided to display various colors, as well as color conversion layers QDr and QDg and a transmission layer TL, and therefore, there is no problem in displaying pure red, green, and/or blue colors.

Each of the first functional layers FLa-1, FLb-1, FLc-1, and FLd-1 may include a hole injection layer and a hole transfer layer, and each of the second functional layers FLa-2, FLb-2, FLc-2, and FLd-2 may include an electron transfer layer and an electron injection layer. In an embodiment, some of the first functional layers FLa-1, FLb-1, FLc-1, and FLd-1 may not include the hole injection layer or the hole transfer layer, and some of the second functional layers FLa-2, FLb-2, FLc-2, and FLd-2 may not include the electron transfer layer or the electron injection layer. In an embodiment, the hole injection layer and the electron injection layer may be included only in the first functional layer FLa-1 and the second functional layer FLd-2 close to the anode Anode or the cathode Cathode, the hole injection layer may be in contact with the anode Anode, and the electron injection layer may be in contact with the cathode Cathode. The intermediate connecting layers INC1, INC2, and INC3 may be located between the electron transfer layer and the hole transfer layer and may also be referred to as charge generation layers. The intermediate connecting layers INC1, INC2, and INC3 may reduce a Fermi barrier between two adjacent functional layers. The LED having the tandem structure emits green light and blue light, but may display various colors and white color due to the color conversion layers QDr and QDg, the transmission layer TL, and the color filters 230R, 230G, and 230B above the LED. In an embodiment, unlike in FIG. 2, the positions of the four emission layers EMLb1, EMLb2, EMLb3, and EMLg may be changed, and for example, the emission layer EMLg that emits green light may be positioned at a height lower than or between the emission layers EMLb1, EMLb2, and EMLb3 that emits light of a blue wavelength.

In an embodiment, the tandem structure may include at least two emission layers, and in various modified examples, the tandem structure may include only one emission layer.

In case that FIGS. 1 and 2 are combined with each other, in a light-emitting display device according to an embodiment, an LED emits green light and blue light, and a scattering absorption layer RCC with a cyan color filter is provided only in an area overlapping a red pixel PXr.

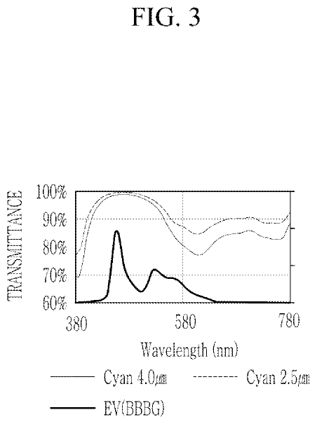

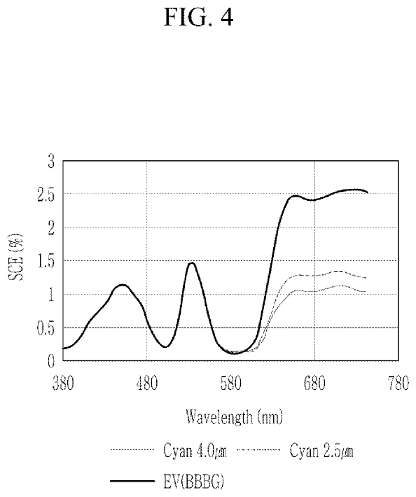

Characteristics of such a scattering absorption layer will be described in detail with reference to FIGS. 3 and 4 below.

FIGS. 3 and 4 are graphs showing characteristics of a scattering absorption layer according to an embodiment.

First, FIG. 3 illustrates a distribution EV(BBBG) of light emitted from an LED according to a wavelength range and a transmittance of a scattering absorption layer RCC with a cyan color filter according to a thickness thereof. FIG. 3 illustrates an example in which the scattering absorption layer RCC has a thickness of about 4.0 μm (Cyan 4.0 μm) and an example in which the scattering absorption layer RCC has a thickness of about 2.5 μm (Cyan 2.5 μm).

Referring to an EV(BBBG) line of FIG. 3, it can be seen that the light emitted from the LED may include a largest amount of light in a blue wavelength band and a small amount of light in a green wavelength band but does not include light in a red wavelength band. This is because in the LED that may include the four emission layers EMLb1, EMLb2, EMLb3, and EMLg, the emission layers EMLb1, EMLb2, and EMLb3 emit blue light, and the emission layer EMLg emits green light as shown in FIG. 2.

A Cyan 4.0 μm line and a Cyan 2.5 μm line of FIG. 3 show that as a thickness of the scattering absorption layer RCC increased, a transmittance thereof decreased. A transmittance of the scattering absorption layer RCC for light in the blue and green wavelength bands was relatively high but was relatively low for light in the red wavelength band. Generally, the transmittance of the scattering absorption layer RCC was about 50% or more in the visible light wavelength band. Therefore, the light in the red wavelength band was also transmitted although a transmittance thereof was relatively low. For example, according to an embodiment, the scattering absorption layer RCC may be formed of the same material or a similar material as the cyan color filter but may have a high transmittance, for example, about 50% or more, unlike a general color filter. Therefore, the scattering absorption layer RCC may transmit light in blue and green wavelength bands, transmit some of light in a red wavelength band, and block or absorb some of the remaining light in the red wavelength band. In contrast, a general cyan color filter is different from the scattering absorption layer RCC in that it has a transmittance of less than about 50% (a transmittance in a range of about 30 to about 40%) and absorbs or blocks light in the red wavelength band to prevent the transmission thereof. According to the scattering absorption layer RCC having the above characteristics, a transmittance of light is not extremely low, thus preventing an excessive reduction in the light efficiency of the light-emitting display device. The cyan color filter may be formed to a small thickness so that the scattering absorption layer RCC may have a transmittance of about 50% or more.

FIG. 4 illustrates a diffuse reflection (SCE) rate for each wavelength band, in which as shown in FIG. 3, an example in which the scattering absorption layer RCC has a thickness of about 4.0 μm (Cyan 4.0 μm) and an example in which the scattering absorption layer RCC has a thickness of about 2.5 μm (Cyan 2.5 μm) are shown, and a comparative example in which the scattering absorption layer RCC is not provided is additionally shown.

In the comparative example of FIG. 4, a degree of diffuse reflection (SCE) for each wavelength band shows that a diffuse reflection (SCE) rate in the red wavelength band was high and was two or more higher than those in the blue and green wavelength bands, for example, diffuse reflection (SCE) occurred to a large extent in the red wavelength band.

Therefore, in the embodiment of FIG. 1, the scattering absorption layer RCC is used to achieve a high transmittance for a cyan color and reduce a transmittance for light of a red wavelength as shown in FIG. 3. Thus, as indicated by a Cyan 4.0 μm line and a Cyan 2.5 μm line of FIG. 4, the diffuse reflection (SCE) rate in the red wavelength band decreased to correspond to those in the blue wavelength band and the green wavelength band. As a result, a total diffuse reflection (SCE) rate in the light-emitting display device was reduced.

Referring to FIG. 4, as a thickness of the scattering absorption layer RCC increased, the diffuse reflection (SCE) rate decreased. Therefore, the thickness of the scattering absorption layer RCC to be formed may be adjusted according to a target value to which the diffuse reflection SCE rate should be decreased.

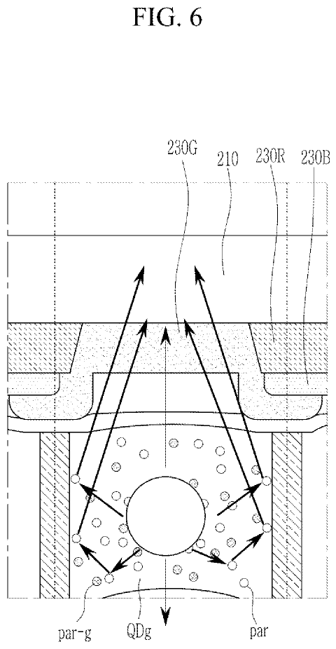

FIG. 4 has been described above with respect to diffuse reflection (SCE), and reflections occurring in the light-emitting display device will be described in more detail with reference to FIGS. 5 and 6 below.

FIGS. 5 and 6 are schematic diagrams for describing characteristics of diffuse reflection.

First, two types of reflections occurring in a light-emitting display device will be individually described with reference to FIG. 5 below.

FIG. 5A illustrates specular reflection, and FIG. 5B illustrates diffuse reflection. Generally, reflection is largely divided into specular reflection (SCI) in which light is reflected symmetrically about incident light as shown in FIG. 5A and diffuse reflection (SCE) in which light is reflected in all directions regardless of incident light as shown in FIG. 5B.

Table 1 shows a result of measuring specular reflection (SCI) and diffuse reflection (SCE) in each of a light-emitting display device including only an upper display panel and a light-emitting display device including upper and lower display panel bonded to each other.

TABLE 1

| | Red color conversion | | Green color conversion | |
|---|---|---|---|---|
| | layer QDr and | | layer QDg and green | |
| | red color filter 230R | | color filter 230G | |
| | Specular | Diffuse | Specular | Diffuse |
| | reflection | reflection | reflection | reflection |
| | (SCI) | (SCE) | (SCI) | (SCE) |
| Upper display | 1.42 | 0.27 | 1.79 | 0.90 |
| panel | | | | |
| Light-emitting | 1.77 | 0.57 | 2.16 | 1.26 |
| display device | | | | |
| Reflection | 0.35 | 0.29 | 0.37 | 0.36 |
| difference | | | | |

Referring to Table 1 above, it can be seen that specular reflection (SCI) and diffuse reflection (SCE) occurred to a small extent in the light-emitting display device including only the upper display panel but occurred to a large extent in the light-emitting display device including the upper and lower display panels bonded to each other.

It appears that the difference in reflectance between before and after the upper and lower display panels were bonded to each other is due to an increase in diffuse reflection, caused by light reflected from the anode Anode and provided in an upward direction after the upper and lower display panels were bonded to each other.

Although the sum of a rate of specular reflection (SCI) and a rate of diffuse reflection (SCE) occurring in the light-emitting display device is determined as a total reflectance, a reflectance that a user may sense is greatly affected by diffuse reflection (SCE) and thus it is necessary to reduce diffuse reflection (SCE).

Causes of diffuse reflection (SCE) occurring in a light-emitting display device as described above will be described with reference to FIG. 6 below.

FIG. 6 is a schematic diagram illustrating the green color conversion layer QDg and the green color filter 230G of the green pixel PXg of FIG. 1, in which a path in which light is emitted to a front surface of the light-emitting display device while being scattered by one scattering member part of the green color conversion layer QDg, which is shown in an expanded view, in various directions is shown.

Referring to FIG. 6, in the case of diffuse reflection (SCE) in the light-emitting display device, light incident from the outside is reflected from the anode Anode and scattered by the scattering members part and the semiconductor nanocrystals par-r and par-g included in the color conversion layers QDr and QDg, and the reflection and scattering of incident light are repeatedly performed while the path is cycled, thereby greatly increasing a reflectance. To reduce the scattering of the incident light, the scattering members part and the semiconductor nanocrystals par-r and par-g may be reduced in the color conversion layers QDr and QDg but the light efficiency of the light-emitting display device may decrease ad thus this method is difficult to be used directly. Accordingly, in an embodiment, the scattering absorption layer RCC is provided on the light-emitting display device to reduce diffuse reflection. For example, in FIG. 1, some of red light scattered in the red color conversion layer QDr may be absorbed by the scattering absorption layer RCC overlapping the red color conversion layer QDr to reduce the amount of red light scattered by diffuse reflection (SCE), thereby reducing a total diffuse reflection (SCE) rate.

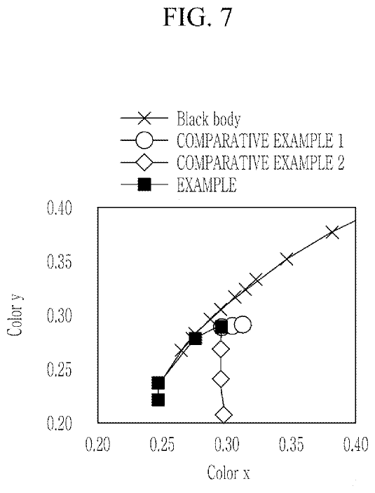

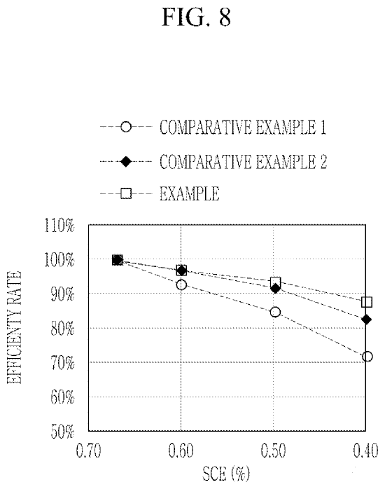

Additional characteristics of the light-emitting display device including the scattering absorption layer RCC will be described with reference to FIGS. 7 and 8 below.

In FIGS. 7 and 8, Comparative example 1, Comparative example 2, and an Example are compared with one another. In Comparative example 1, transmittances of red light, green light, and blue light among external light were reduced at the same time in an upper display panel to maintain a reflected color. In Comparative example 2, transmittance of green light was reduced in an upper display panel to change a reflected color. In contrast, in the Example, the scattering absorption layer RCC was additionally provided in an upper display panel as shown in FIG. 1.

First, features of color coordinates will be described with reference to FIG. 7.

FIG. 7 is a schematic diagram illustrating color coordinate characteristics of a light-emitting display device according to an embodiment.

FIG. 7 illustrates a black body curve of color coordinates on which a reference value is shown.

In Comparative example 1, all the transmittances of red light, green light, and blue light were reduced and thus a rate of change of actual color coordinate values was not high, but in Comparative example 2, only the transmittance of green light was reduced, thus causing reddishness, and therefore, color coordinate values decreased along a Y-axis and was away from the black body curve that is a criterion.

In contrast, in the Example, the scattering absorption layer RCC was additionally provided without adjusting the transmittances of red light, green light, and blue light, so that diffuse reflection (SCE) occurring internally along the black body curve may be basically reduced by the scattering absorption layer RCC.

A light efficiency rate, for example, display efficiency (luminance efficiency) of a light-emitting display device in case that a voltage is applied thereto will be described with reference to FIG. 8 below.

FIG. 8 is a graph showing light efficiency of a light-emitting display device according to an embodiment.

Referring to FIG. 8, in Comparative example 1, all the transmittances of red light, green light, and blue light were reduced, thus resulting in a sharp reduction in a light efficiency rate, and in Comparative example 2, only the transmittance of green light was reduced, thus resulting in a reduction in light efficiency rate but a rate of the reduction was less than that in Comparative example 1.

In contrast, in the Example, only the scattering absorption layer RCC was additionally provided without adjusting the transmittances of red light, green light, and blue light and thus basically, a reduction in light efficiency rate was less than those in Comparative examples 1 and 2.

In FIG. 8, as the light efficiency rate decreases, a diffuse reflection (SCE) decreases, because the higher a display luminance, the higher a diffuse reflection (SCE) rate.

In case that FIGS. 7 and 8 are combined with each other, in an embodiment, because the transmittances of red light, green light, and blue light among external light are not adjusted and the scattering absorption layer RCC is additionally provided, color coordinate values of a reflected color are not arbitrarily changed, thus preventing a reduction in display quality, a reduction in light efficiency may be minimized, and diffuse reflection (SCE) may decrease due to the scattering absorption layer RCC.

Therefore, in the light-emitting display device of an embodiment, a reduction in light efficiency may be minimized, a reflectance, and for example, a diffuse reflection (SCE) rate may be decreased, and a reflected color may be maintained constant by using the scattering absorption layer RCC.

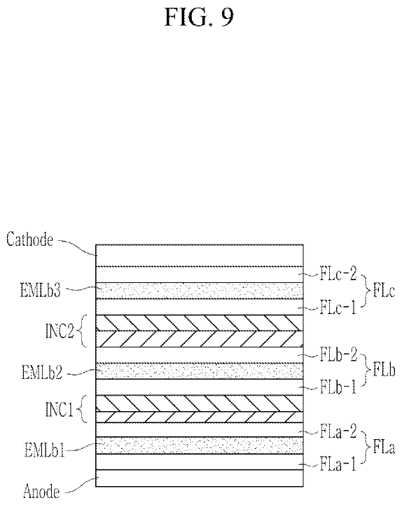

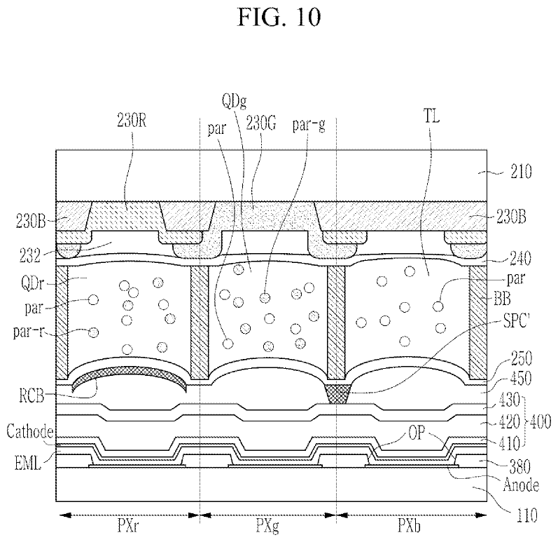

Embodiments of FIGS. 9 and 10, which may be different from those of FIGS. 1 and 2, will be described in detail below. First, a schematic cross-sectional structure of an LED according to an embodiment will be described with reference to FIG. 9.

FIG. 9 is a schematic cross-sectional view of a light-emitting diode according to an embodiment.

FIG. 9 illustrates a stacked structure of an LED having a tandem structure including emission layers EML, and in the embodiment of FIG. 9, a total of three emission layers EML are included between an anode Anode and a cathode Cathode. Each of functional layers FLa, FLb, and FLc is provided on or below one of emission layer EMLb1, EMLb2, and EMLb3, and intermediate connecting layers INC1 and INC2 are positioned between adjacent functional layers. For example, in the LED having the tandem structure of FIG. 9, the anode Anode, a first functional layer FLa-1 for a first emission layer, the first emission layer EMLb1, a second functional layer FLa-2 for the first emission layer, the first intermediate connecting layer INC1, a first functional layer FLb-1 for a second emission layer, the second emission layer EMLb2, a second functional layer FLb-2 for the second emission layer, the second intermediate connecting layer INC2, a first functional layer FLc-1 for a third emission layer, the third emission layer EMLb3, a second functional layer FLc-2 for the third emission layer, and the cathode Cathode may be sequentially stacked each other.

In the embodiment of FIG. 9, the emission layers EMLb1, EMLb2, and EMLb3 emit light of a blue wavelength, and an emission layer that emits light of a green wavelength is not provided unlike in FIG. 2. Here, the emission layers EMLb1, EMLb2, and EMLb3 that emit light of a blue wavelength may be formed of the same material or a similar material to emit light of the same wavelength or be formed of different materials to emit light of different wavelength bands among pieces of blue light. In case that the LED including the three emission layers EMLb1, EMLb2, and EMLb3 emits blue light, pure red, green and/or blue colors may be displayed through not only color conversion layers QDr and QDg and a transmission layer TL included in an upper display panel but also color filters 230R, 230G, and 230B.

Each of the first functional layers FLa-1, FLb-1, and FLc-1 may include a hole injection layer and a hole transfer layer, and each of the second functional layers FLa-2, FLb-2, and FLc-2 may include an electron transfer layer and an electron injection layer. In an embodiment, some of the first functional layers FLa-1, FLb-1, and FLc-1 may not include the hole injection layer or the hole transfer layer, and some of the second functional layers FLa-2, FLb-2, and FLc-2 may not include the electron transfer layer or the electron injection layer. In an embodiment, the hole injection layer and the electron injection layer may be included only in the first functional layer FLa-1 and the second functional layer FLd-2 close to the anode Anode or the cathode Cathode, the hole injection layer may be in contact with the anode Anode, and the electron injection layer may be in contact with the cathode Cathode. The intermediate connecting layers INC1 and INC2 may be located between the electron transfer layer and the hole transfer layer and may also be referred to as charge generation layers. The intermediate connecting layers INC1 and INC2 may reduce a Fermi barrier between two adjacent functional layers. The LED having the tandem structure emits blue light but may display various colors and white color due to the color conversion layers QDr and QDg, the transmission layer TL, and the color filters 230R, 230G, and 230B above the LED.

In an embodiment, the tandem structure may include at least two emission layers, and in various modified examples, the tandem structure may include only one emission layer.

A light-emitting display device including the LED having the tandem structure of FIG. 9 may have a schematic cross-sectional structure as shown in FIG. 10.

FIG. 10 is a schematic cross-sectional view of a light-emitting display device according to an embodiment.

The light-emitting display device of FIG. 10 is structurally the same as that of FIG. 1. However, the light-emitting display device of FIG. 10 may include a scattering absorption layer RCB different from the scattering absorption layer RCC of FIG. 1. For example, in FIG. 1, the scattering absorption layer RCC with the cyan color filter is provided, whereas in FIG. 10, the scattering absorption layer RCB with a blue color filter is provided. A spacer SPC′ is also formed as a blue color filter unlike in FIG. 1.

For example, the scattering absorption layer RCB and the spacer SPC′ each including the blue color filter are positioned below a second passivation layer 250. The scattering absorption layer RCB and the spacer SPC′ may be formed of the same material or a similar material by the same process. In the embodiment of FIG. 10, the scattering absorption layer RCB and the spacer SPC′ may be each embodied as blue color filters that transmit blue light. However, in an embodiment, the scattering absorption layer RCB and the spacer SPC′ may be formed of different materials, and the spacer SPC′ may not be formed as a blue color filter. However, in case that the same material or a similar material and the same process are used, the process may be simplified, thus reducing a manufacturing time.

The scattering absorption layer RCB has a total transmittance of more than about 50% in a visible light wavelength band, similar to the scattering absorption layer RCC of FIG. 1. For example, according to an embodiment, the scattering absorption layer RCB may be formed of the same material or a similar material as the blue color filter but may have a high transmittance, for example, about 50% or more, unlike a general color filter. As a result, the scattering absorption layer RCB transmits blue light and transmits some of light in a red or green wavelength band but blocks or absorbs some of the light in the red or green wavelength band. In contrast, a general blue color filter is different from the scattering absorption layer RCB in that it has a transmittance of less than about 50% (a transmittance of about 33%) and absorbs or blocks light in the red and green wavelength bands to prevent the transmission thereof. According to the scattering absorption layer RCB having the above characteristics, a transmittance of light is not extremely low, thus preventing an excessive reduction in the light efficiency of the light-emitting display device. The blue color filter may be formed to a small thickness so that the scattering absorption layer RCB may have a transmittance of about 50% or more.

The scattering absorption layer RCB including the blue color filter of the embodiment of FIG. 10 is located only in an area overlapping a red pixel PXr. For example, the scattering absorption layer RCB is formed only at a position overlapping a red color filter 230R and a red color conversion layer QDr. The scattering absorption layer RCB may be positioned between the red color conversion layer QDr and an anode Anode of an LED, and may transmit blue light and absorb or block red light and green light.

The spacer SPC′ may be formed at a position that corresponds to a light blocking area and that is higher than the scattering absorption layer RCB. Therefore, the spacer SPC′ may overlap bank parts BB and color filters 230R, 230G, and 230B overlapping one another but may not overlap the color conversion layers QDr and QDg or a transmission layer TL, and may not overlap the color filters 230R, 230G, and 230B that do not overlap one another. The spacer SPC′ may maintain a constant interval between an upper display panel and a lower display panel.

In case that FIGS. 9 and 10 are combined with each other, in a light-emitting display device according to an embodiment, an LED emits blue light, and a scattering absorption layer RCB with a blue color filter is provided only in an area overlapping a red pixel PXr.

Based on FIGS. 1 and 2, in a light-emitting display device of an embodiment, an LED emits green light and blue light, and a scattering absorption layer RCC with a cyan color filter that transmits green light and blue light is provided.

According to the previous embodiments, a light-emitting display device may include a scattering absorption layer that transmits light of a wavelength emitted from an LED, and the scattering absorption layer prevent diffuse reflection (SCE) from occurring to a large extent in a red wavelength band as shown in FIG. 4, thereby reducing a total diffuse reflection (SCE) rate.

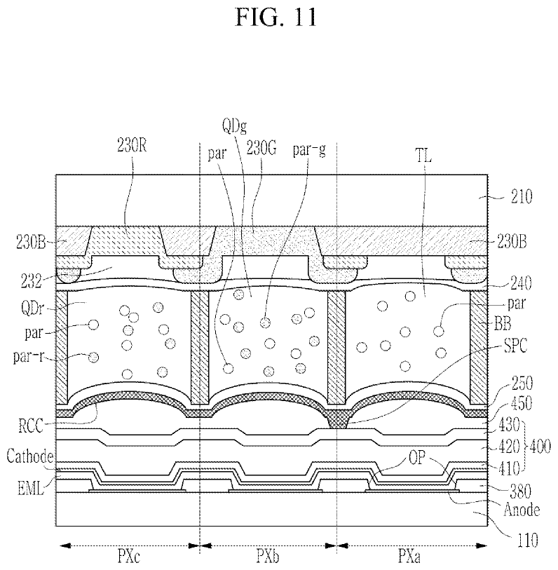

FIGS. 1 and 10 illustrate embodiments in which the scattering absorption layers RCC and RCB are positioned only in an area overlapping the red pixel PXr. However, the scattering absorption layer may be provided in an area other than the area overlapping the red pixel PXr, and various modified examples in which a position of a scattering absorption layer is changed will be described in FIGS. 11 to 16 below.

FIGS. 11 to 16 are schematic cross-sectional views of light-emitting display devices according to other embodiments.

FIGS. 11 to 16 illustrate modified examples in which an LED may include four emission layers EMLb1, EMLb2, EMLb3, and EMLg that emit green light and blue light as shown in FIG. 2, and may include a scattering absorption layer RCC formed as a cyan color filter as shown in FIG. 1. The modified examples described below are applicable to the embodiments of FIGS. 9 and 10 but may be different from the embodiments of FIGS. 9 and 10 in which the LED emits blue light and may include the scattering absorption layer RCB formed as a blue color filter.

First, the embodiment of FIG. 11 will be described.

Unlike in FIG. 1, the scattering absorption layer RCC is formed on the entire LED and is integrally formed with a spacer SPC. The scattering absorption layer RCC of FIG. 11 overlaps all a bank part BB, color conversion layers QDr and QDg, and a transmission layer TL, and also overlaps both a transmissive area and a light blocking area of color filters 230R, 230G, and 230B.

A portion of the scattering absorption layer RCC that overlaps the bank part BB and has a large thickness may be the spacer SPC. In an embodiment, the spacer SPC and the scattering absorption layer RCC may be formed of different materials, and, the spacer SPC may be formed of a material other than the cyan color filter.

In the embodiment of FIG. 11, some of red light scattered in the red color conversion layer QDr may be absorbed by the scattering absorption layer RCC, which overlaps the red color conversion layer QDr of a red pixel PXr, to reduce the amount of red light scattered by diffuse reflection (SCE), thereby reducing a total diffuse reflection (SCE) rate. In the embodiment of FIG. 11, the amount of red light absorbed by the scattering absorption layer RCC overlapping a green pixel PXg and a blue pixel PXb may not be large, but referring to FIG. 4, red light is scattered by diffuse reflection (SCE) to a large extent and thus a total diffuse reflection (SCE) rate may be reduced by absorbing some of the scattered red light.

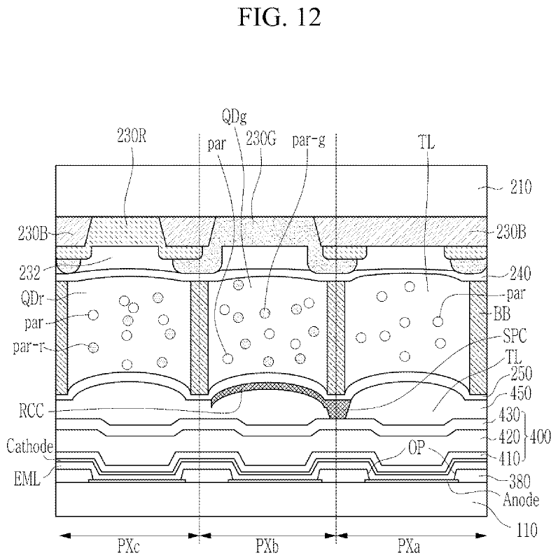

The embodiment of FIG. 12 will be described below.

In the embodiment of FIG. 12, a scattering absorption layer RCC is located only in an area overlapping a green pixel PXg unlike in FIG. 1. For example, in the embodiment of FIG. 12, the scattering absorption layer RCC including a cyan color filter is located only in an area overlapping the green pixel PXg and formed only at a position overlapping a green color filter 230G and a green color conversion layer QDg. In an embodiment of FIG. 12, a spacer SPC and the scattering absorption layer RCC may be integrally formed.

In the embodiment of FIG. 12, the amount of red light absorbed by the scattering absorption layer RCC overlapping the green pixel PXg may not be large compared to the embodiments of FIGS. 1 and 11, but referring to FIG. 4, red light is scattered by diffuse reflection (SCE) to a large extent and thus a total diffuse reflection (SCE) rate may be reduced by absorbing some of the scattered red light.

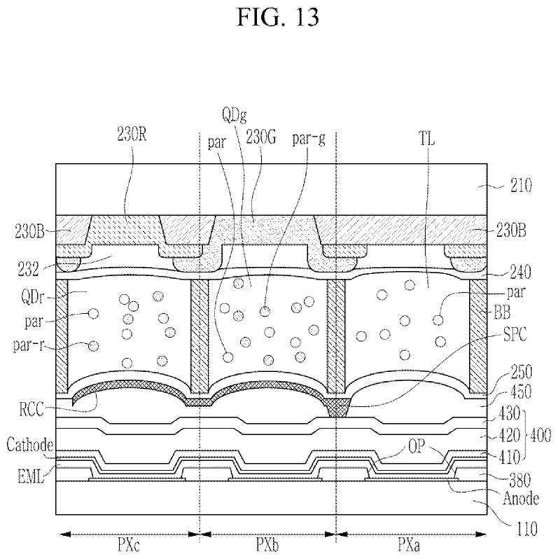

The embodiment of FIG. 13 will be described below.

In FIG. 13, the scattering absorption layer RCC is located only in an area overlapping a red pixel PXr and a green pixel PXg. In the embodiment of FIG. 13, a spacer SPC and the scattering absorption layer RCC may be integrally formed.

In the embodiment of FIG. 13, some of red light scattered in the red color conversion layer QDr may be absorbed by the scattering absorption layer RCC, which overlaps a red color conversion layer QDr of a red pixel PXr, to reduce the amount of red light scattered by diffuse reflection (SCE), thereby reducing a total diffuse reflection (SCE) rate. In the embodiment of FIG. 13, although the amount of red light absorbed by the scattering absorption layer RCC overlapping the green pixel PXg may not be large, referring to FIG. 4, red light is scattered by diffuse reflection (SCE) to a large extent and thus a total diffuse reflection (SCE) rate may be reduced by absorbing some of the scattered red light.

Unlike in FIGS. 1 and 11 to 13, the scattering absorption layer RCC may overlap various pixels, and at least one of the red pixel PXr, the green pixel PXg, and a blue pixel PXb may overlap the scattering absorption layer RCC. However, in case that it is necessary to significantly reduce the diffuse reflection (SCE) rate, the scattering absorption layer RCC may overlap the red color conversion layer QDr of the red pixel PXr.

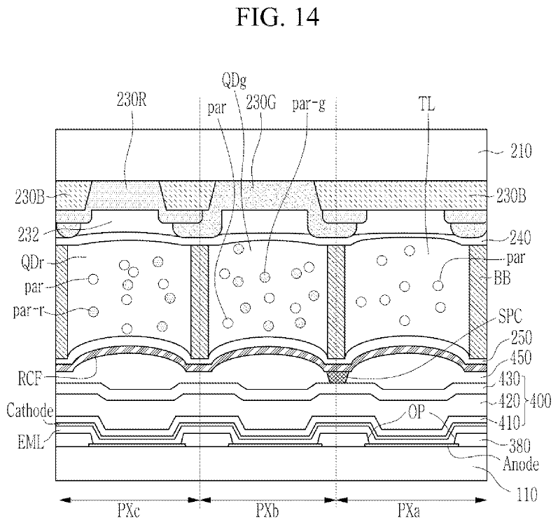

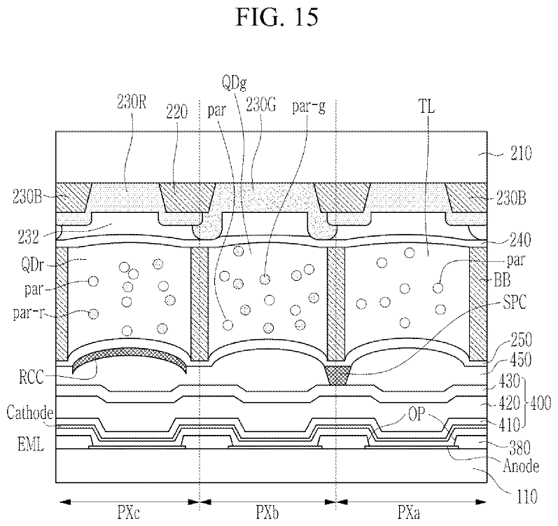

Modifications to the position of the scattering absorption layer RCC have been described above. Other modified examples will be described with reference to FIGS. 14 and 15 below.

First, FIG. 14 illustrates an embodiment in which a scattering absorption layer is not formed as a color filter but is formed using a film.

In FIG. 14, a scattering absorption film RCF is formed on an entire light-emitting display device. The scattering absorption film RCF of FIG. 14 overlaps all a bank part BB, color conversion layers QDr and QDg, and a transmission layer TL, and also overlaps both a transmissive area and a light blocking area of color filters 230R, 230G, and 230B. Here, the scattering absorption film RCF may transmit light in blue and green wavelength bands and absorb light in a red wavelength band. The scattering absorption film RCF may have a transmittance of about 50% or more.

In FIG. 14, a spacer SPC may be formed below the scattering absorption film RCF and located at a position overlapping the bank part BB.

In the embodiment of FIG. 14, similar to the scattering absorption film RCF of FIG. 11, the scattering absorption film RCF may absorb some of red light scattered in a red color conversion layer QDr to reduce the amount of red light scattered by diffuse reflection (SCE), thereby reducing a total diffuse reflection (SCE) rate. In the embodiment of FIG. 11, the amount of red light to be absorbed by the scattering absorption layer RCC overlapping a green pixel PXg and a blue pixel PXb may not be large, but referring to FIG. 4, red light is scattered by diffuse reflection (SCE) to a large extent and thus a total diffuse reflection (SCE) rate may be reduced by absorbing some of the scattered red light.

FIG. 15 is a modified example of FIG. 1, in which a light blocking area is formed by forming a light blocking member 220 rather than by forming color filters 230R, 230G, and 230B to have a high height while overlapping one another.

The light blocking member 220 may be formed of an organic material including black pigment that does not transmit light, similar to a bank part BB. The light blocking member 220 may be configured to divide a transmissive area in which the color filters 230R, 230G, and 230B are located and be located between neighboring color filters 230R, 230G, and 230B.

The embodiment of FIG. 15 is the same as the embodiment of FIG. 1 in that a diffuse reflection (SCE) rate is reduced but a reflectance due to specular reflection in the light blocking member 220 may be higher than that that due to specular reflection in the blue color filter 230B of FIG. 1. Thus, a total reflectance in the embodiment of FIG. 1 may be lower than that in the embodiment of FIG. 15.

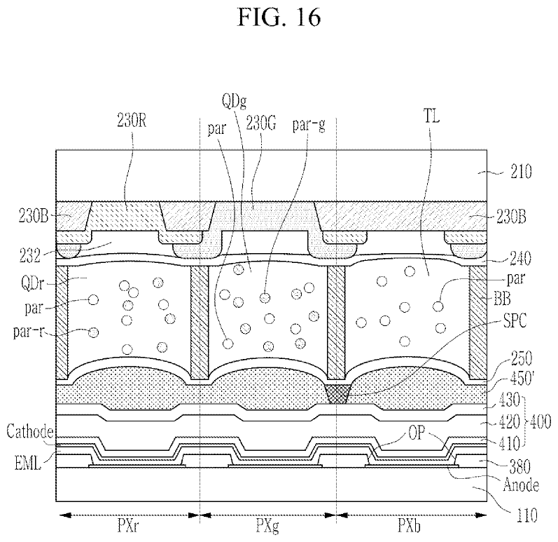

In the above modified examples, the scattering absorption layer RCC or RCB is located below the second passivation layer 250 in a schematic cross-sectional view. However, various modifications may be made, provided the scattering absorption layer RCC or RCB is located on the anode Anode and below the color conversion layers QDr and QDg and the transmission layer TL. For example, as in the embodiment of FIG. 16, the scattering absorption layer RCC or RCB may not be formed, and a filling layer 450′ may be formed to have characteristics of the scattering absorption layer RCC or RCB. For example, the filling layer 450′ may include a cyan color filter or a blue color filter to have optical characteristics of the scattering absorption layer RCC or RCB. Therefore, in the embodiment of FIG. 16, the scattering absorption layer RCC or RCB may not be formed.

In an embodiment, the scattering absorption layer RCC or RCB may include a polymer or a resin although it is described above that the scattering absorption layer RCC or RCB may include a color filter. Even in case that the scattering absorption layer RCC or RCB may include the polymer or resin, the scattering absorption layer RCC or RCB should have transmittance characteristics described above with reference to FIGS. 1 and 10.

In the schematic cross-sectional views described above, structures between the anode Anode and the first substrate 110 are omitted. One of schematic cross-sectional structures between the anode Anode and the first substrate 110 will be described through an embodiment of FIG. 17 below.

FIG. 17 is a schematic diagram illustrating a schematic cross-sectional structure of a lower display panel according to an embodiment.

FIG. 17 illustrates an embodiment including a polycrystalline transistor LTPS TFT and an oxide transistor Oxide TFT. In an embodiment, only the polycrystalline transistor or the oxide transistor may be provided.

An overall structure of a lower display device of a light-emitting display panel according to an embodiment will be described in greater detail below.

Referring to FIG. 17, a metal layer BML is provided on a first substrate 110.

The first substrate 110 may include a material, for example, glass, which has rigid properties and thus is not bendable, or a flexible material, for example, plastic or polyimide, which is bendable. In case that the first substrate 110 is a flexible substrate, a two-layer barrier layer in which a polyimide and an inorganic insulating material are sequentially formed may be formed dually.

The metal layer BML may be formed at a position overlapping a channel of a driving transistor of a first semiconductor layer ACT1, which is subsequentially formed, on a plane, and is also referred to as a lower sealing layer. The metal layer BML may include a metal such as copper (Cu), molybdenum (Mo), aluminum (Al), or titanium (Ti) or a metal alloy thereof. Here, the driving transistor may be a transistor that generates a current to be transmitted to an LED.

A buffer layer 111 is provided on the first substrate 110 and the metal layer BML to cover the first substrate 110 and the metal layer BML. The buffer layer 111 may block the penetration of impurity elements into the first semiconductor layer ACT1, and be an inorganic insulating film including silicon oxide (SiOₓ), silicon nitride (SiNₓ), silicon oxynitride (SiONₓ), or the like within the spirit and the scope of the disclosure.

The first semiconductor layer ACT1 formed of a silicon semiconductor (for example, a polycrystalline semiconductor P-Si) is positioned on the buffer layer 111. The first semiconductor layer ACT1 may include the channel of the polycrystalline transistor including the driving transistor, and a first area and a second area located at both sides thereof. Here, the polycrystalline transistor may include not only the driving transistor but also polycrystalline switching transistors. Areas having conductive characteristics may be formed at the both sides of the channel of the first semiconductor layer ACT1 by plasma treatment or doping to function as a first electrode and a second electrode.

A first gate insulating film 141 may be provided on the first semiconductor layer ACT1. The first gate insulating film 141 may be an inorganic insulating film including silicon oxide (SiOₓ), silicon nitride (SiNₓ), silicon oxynitride (SiONₓ), or the like within the spirit and the scope of the disclosure.

A first gate conductive layer including a gate electrode GE1 of the polycrystalline transistor may be provided on the first gate insulating film 141. The first gate conductive layer may be provided with a scan line or an emission control line, as well as the gate electrode GE1 of the polycrystalline transistor. In an embodiment, first gate conductive layer formed of different materials may be divided into a first-first gate conductive layer and a first and second gate conductive layer.

After the first gate conductive layer is formed, a plasma treatment or doping process may be performed to make an exposed region of the first semiconductor layer ACT1 have conductive properties. For example, a portion of the first semiconductor layer ACT1 hidden by the first gate conductive layer may not have conductive properties, and a portion thereof that is not covered with the first gate conductive layer may have the same characteristics as a conductive layer.

A second gate insulating film 142 may be provided on the first gate conductive layer and the first gate insulating film 141. The second gate insulating film 142 may be an inorganic insulating film including silicon oxide (SiOₓ), silicon nitride (SiNₓ), silicon oxynitride (SiONₓ), or the like within the spirit and the scope of the disclosure.

A second gate conductive layer including an electrode CE of a storage capacitor may be provided on the second gate insulating film 142. The electrode CE of the storage capacitor overlaps a gate electrode GE1 of the driving transistor to form the storage capacitor.

In an embodiment, the second gate conductive layer may further include a lower shielding layer BML-1 of an oxide transistor. In case that an additional conductive layer is formed as in the embodiments of FIGS. 7 and 8, the lower shielding layer BML-1 of the oxide transistor may be formed as an additional conductive layer. The lower shielding layer BML-1 of the oxide transistor may be located below the channel of the oxide transistor to shield the channel from light, electromagnetic interference, etc. generated below the channel of the oxide transistor.

In an embodiment, the second gate conductive layer may further include a scan line, a control line, or a voltage line. The second gate conductive layer may include a metal such as copper (Cu), molybdenum (Mo), aluminum (Al), or titanium (Ti), or a metal alloy thereof, and may be formed in a single layer or multiple layers.

A first interlayer insulating film 161 may be provided on the second gate conductive layer. The first interlayer insulating film 161 may include an inorganic insulating film including silicon oxide (SiOₓ), silicon nitride (SiNₓ), silicon oxynitride (SiONₓ), or the like, and in an embodiment, an inorganic insulating material may be formed to a large thickness.

A second semiconductor layer (oxide semiconductor layer) including a second semiconductor ACT2, which may include a channel of an oxide transistor, a first area, and a second area, may be provided on the first interlayer insulating film 161.

A third gate insulating film 143 may be provided on the second semiconductor layer. The third gate insulating film 143 may be provided on the entire second semiconductor layer and first interlayer insulating film 161. The third gate insulating film 143 may include an inorganic insulating film including silicon oxide (SiOₓ), silicon nitride (SiNₓ), silicon oxynitride (SiONₓ), or the like within the spirit and the scope of the disclosure.

A third gate conductive layer including a gate electrode GE3 of an oxide transistor may be provided on the third gate insulating film 143. The gate electrode GE3 of the oxide transistor may overlap the channel. The third gate conductive layer may further include a scan line or a control line. The third gate conductive layer may include a metal such as copper (Cu), molybdenum (Mo), aluminum (Al), or titanium (Ti) or a metal alloy thereof, and may be formed in a single layer or multiple layers.

A second interlayer insulating film 162 may be provided on the third gate conductive layer. The second interlayer insulating film 162 may have a single-layer or multi-layer structure. The second interlayer insulating film 162 may include an inorganic insulating material such as silicon nitride (SiNₓ), silicon oxide (SiOₓ), or silicon nitrate (SiOₓN_{y}), and may include an organic material according to an embodiment.

A first data conductive layer including a connecting member to be connected to the first area of the polycrystalline transistor and the second area of the oxide transistor may be provided on the second interlayer insulating film 162. The first data conductive layer may include a metal such as aluminum (Al), copper (Cu), molybdenum (Mo), or titanium (Ti) or a metal alloy thereof, and may be formed in a single layer or multiple layers.

A first organic film 181 may be provided on the first data conductive layer. The first organic film 181 may be an organic insulating film including an organic material, and the organic material may include at least one material selected from the group consisting of polyimide, polyamide, acrylic resin, benzocyclobutene, and phenol resin.

A second data conductive layer including an anode connecting member ACM2 may be provided on the first organic film 181. The second data conductive layer may include a data line or a driving voltage line. The second data conductive layer may include a metal such as aluminum (Al), copper (Cu), molybdenum (Mo), or titanium (Ti) or a metal alloy thereof, and may be formed in a single layer or multiple layers. The anode connecting member ACM2 is connected to the first data conductive layer through an opening OP3 in the first organic film 181.

A second organic film 182 and a third organic film 183 are provided on the second data conductive layer, and an anode connection opening OP4 is formed in the second organic film 182 and the third organic film 183. The anode connecting member ACM2 is electrically connected to the anode Anode through an anode connection opening OP4. The second organic film 182 and the third organic film 183 may be organic insulating films, and may include at least one material selected from the group consisting of polyimide, polyamide, acrylic resin, benzocyclobutene, and phenol resin. In an embodiment, the third organic film 183 may be omitted.

A pixel defining film 380 having an opening OP exposing the anode Anode and covering at least a part of the anode Anode may be provided on the anode Anode. The pixel defining film 380 may be a black pixel defining film formed of a black organic material to prevent light, which is supplied from the outside, from being reflected to the outside, and may be formed of a transparent organic material in an embodiment.

A spacer 385 is provided on the pixel defining film 380. The spacer 385 may be formed of a transparent organic insulating material. In an embodiment, the spacer 385 may be formed of a positive transparent organic material. The spacer 385 may include two parts 385-1 and 385-2 having different heights, so that the high part 385-1 may function as a spacer and the low part 385-2 may improve adhesion characteristics between the spacer 385 and the pixel defining film 380.

A functional layer FL and a cathode Cathode may be sequentially formed on the anode Anode, the spacer 385, and the pixel defining film 380, and may be located on entire areas of the anode Anode, the spacer 385, and the pixel defining film 380. An emission layer EML may be provided between parts of the functional layer FL, and located only in an opening OP of the pixel defining film 380. Hereinafter, the functional layer FL and the emission layer EML may be referred to as together as an intermediate layer. The functional layer FL may include at least one of auxiliary layers such as an electron injection layer, an electron transfer layer, a hole transfer layer, and a hole transfer layer, the hole injection layer and the hole transfer layer may be located below the emission layer EML, and the electron transfer layer and the electron injection layer may be located on the emission layer EML.

An encapsulation layer 400 is provided on the cathode Cathode. The encapsulation layer 400 may include at least one inorganic film and at least one organic film, and may have a three-layer structure including a first inorganic encapsulation layer, an organic encapsulation layer, and a second inorganic encapsulation layer. The encapsulation layer 400 may protect the emission layer EML from moisture, oxygen, etc. that may be introduced from the outside. In an embodiment, the encapsulation layer 400 may include a structure in which an inorganic layer and an organic layer may be further sequentially stacked each other.

Sensing insulating layers 501, 510, and 511 and sensing electrodes 540 and 541 are provided on the encapsulation layer 400 to sense a touch. In the embodiment of FIG. 17, a touch may be sensed by a capacitive method using the two sensing electrodes 540 and 541.

For example, the first sensing insulating layer 501 is formed on the encapsulation layer 400, and the sensing electrodes 540 and 541 are formed on the first sensing insulating layer 501. The sensing electrodes 540 and 541 may be insulated with the second sensing insulating layer 510 interposed therebetween, and some thereof may be electrically connected through openings in the sensing insulating layer 510. Here, the sensing electrodes 540 and 541 may include a metal such as aluminum (Al), copper (Cu), silver (Ag), gold (Au), molybdenum (Mo), titanium (Ti), or tantalum (Ta) or a metal alloy thereof, and be formed in a single layer or multiple layers. The third sensing insulating layer 511 is formed on the sensing electrode 540.

Although FIG. 17 illustrates that no components are located on the third sensing insulating layer 511, a film with a polarizing plate may be attached to reduce the reflection of external light or a color filter or a color conversion layer may be further formed to improve color quality. A light blocking member may be positioned between color filters or color conversion layers. In an embodiment, a layer including a material that absorbs light of some wavelengths (hereinafter referred to as a reflection adjustment material) among external light may be further provided. In an embodiment, an additional organic film (also referred to as a planarization film) may be further provided to flatten a front surface of the light-emitting display device.

The embodiment in which a total of three organic films 181, 182, and 183 are formed and an anode connection opening is formed in the second organic film and the third organic film has been described above with reference to FIG. 17. However, at least two organic films may be formed, and, the anode Anode connection opening may be formed in the upper organic film far from a substrate and a lower-organic-film opening may be formed in the lower organic film.

One of the upper display panels of FIGS. 1 and 10 to 15 may be applied as an upper display panel on the structure of the lower display panel of FIG. 17. The structure of the lower display panel may be different from that of FIG. 17.

While the embodiments have been described above in detail, the scope of the disclosure is not limited thereto and various modifications and improvements made by those of ordinary skill in the art using concepts of the disclosure defined in the following claims should be understood to be within the scope of the disclosure.

While this disclosure has been described in connection with what is considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A light-emitting display device comprising:
a light-emitting diode that emits blue light and green light;
a color conversion layer on the light-emitting diode; and
a scattering absorption layer that transmits blue light and green light and disposed between the color conversion layer and the light-emitting diode.

2. The light-emitting display device of claim 1, wherein the light-emitting diode comprises:
an anode;
a cathode; and
three emission layers that emit blue light and an emission layer that emits green light, the emission layers disposed between the anode and the cathode.

3. The light-emitting display device of claim 1, wherein the scattering absorption layer has a transmittance of about 50% or more in a visible light wavelength band.

4. The light-emitting display device of claim 1, wherein
the light-emitting diode comprises a first light-emitting diode, a second light-emitting diode, and a third light-emitting diode,
the color conversion layer comprises a red color conversion layer overlapping the first LED, and a green color conversion layer overlapping the second light-emitting diode, and
the light emitting display device comprises a transmission layer overlapping the third light-emitting diode.

5. The light-emitting display device of claim 4, wherein the scattering absorption layer overlaps the red color conversion layer and comprises a cyan color filter.

6. The light-emitting display device of claim 4, wherein the scattering absorption layer overlaps the green color conversion layer and comprises a cyan color filter.

7. The light-emitting display device of claim 4, wherein the scattering absorption layer overlaps the red color conversion layer, the green color conversion layer, and the transmission layer.

8. The light-emitting display device of claim 7, wherein the scattering absorption layer comprises a cyan color filter.

9. The light-emitting display device of claim 7, wherein the scattering absorption layer is a film.

10. The light-emitting display device of claim 4, further comprising:
a bank part disposed between the red color conversion layer, the green color conversion layer, and the transmission layer and including a black pigment.

11. The light-emitting display device of claim 10, further comprising:
an upper substrate,
a red color filter disposed between the upper substrate and the red color conversion layer;
a green color filter disposed between the upper substrate and the green color conversion layer; and
a blue color filter disposed between the upper substrate and the transmission layer.

12. The light-emitting display device of claim 11, further comprising:
a light blocking area in which the red color filter, the green color filter, and the blue color filter overlap each other,
wherein the blue color filter among the red color filter, the green color filter, and the blue color filter in the light blocking area is closest to the upper substrate.

13. The light-emitting display device of claim 12, wherein
the light blocking area corresponds to an overlapping part of the red color filter, the green color filter, and the blue color filter, and
the light-emitting display device further comprises a low refractive index layer disposed between the red color filter and the red color conversion layer, between the green color filter and the green color conversion layer, and between the blue color filter and the transmission layer.

14. The light-emitting display device of claim 11, further comprising:
a light blocking member disposed between the red color filter, the green color filter, and the blue color filter.

15. The light-emitting display device of claim 1, further comprising:
a lower display panel on which the light-emitting diode is disposed; and
an upper display panel comprising the color conversion layer and the scattering absorption layer, wherein
the upper display panel and the scattering absorption layer are formed of a same material, and
the upper display panel further comprises a spacer that maintains a constant gap between the lower display panel and the upper display panel.

16. A light-emitting display panel comprising:
a light-emitting diode that emits blue light;
a color conversion layer on the light-emitting diode; and
a scattering absorption layer disposed between the color conversion layer and the light-emitting diode, and comprising a blue color filter,
wherein the light-emitting diode comprises:
an anode;
a cathode; and
three emission layers that emit blue light and disposed between the anode and the cathode.

17. The light-emitting display device of claim 16, wherein the scattering absorption layer has a transmittance of about 50% or more in a visible light wavelength band.

18. The light-emitting display device of claim 16, wherein
the light-emitting diode comprises a first light-emitting diode, a second light-emitting diode, and a third light-emitting diode,
the color conversion layer comprises a red color conversion layer overlapping the first light-emitting diode, and a green color conversion layer overlapping the second light-emitting diode,
the light emitting display device further comprises a transmission layer overlapping the third light-emitting diode, and
the scattering absorption layer overlaps the red color conversion layer.

19. The light-emitting display device of claim 18, further comprising:
an upper substrate,
a red color filter disposed between the upper substrate and the red color conversion layer;
a green color filter disposed between the upper substrate and the green color conversion layer; and
a blue color filter disposed between the upper substrate and the transmission layer.

20. The light-emitting display device of claim 16, wherein
a lower display panel on which the light-emitting diode is disposed; and
an upper display panel comprising the color conversion layer and the scattering absorption layer, wherein
the upper display panel and the scattering absorption layer are formed of a same material as the scattering absorption layer, and
the upper display panel further comprises a spacer that maintains a constant gap between the lower display panel and the upper display panel.
